(19) United States
(12) Patent Application Publication
(10) Pub. No.: US 2016/0359087 A1
(43) Pub. Date: Dec. 8, 2016

(54) SEMICONDUCTOR LIGHT EMITTING DEVICE

(71) Applicant: SAMSUNG ELECTRONICS CO., LTD., Suwon-si (KR)

(72) Inventors: Gong Shin LEE, Suwon-si (KR); In Joon YEO, Hwaseong-si (KR); Sung Won KO, Gwangju-si (KR); Shi Young LEE, Seoul (KR); Byung Chul CHOI, Yongin-si (KR)

(73) Assignee: SAMSUNG ELECTRONICS CO., LTD., Suwon-si (KR)

(21) Appl. No.: 15/158,059

(22) Filed: May 18, 2016

(30) Foreign Application Priority Data
Jun. 5, 2015 (KR) 10-2015-0080005

(51) Int. Cl. H01L 33/22; H01L 33/14; H01L 33/32; H01L 33/38; G02F 1/133; F21V 29/70; G02F 1/1343; G02F 1/1335; G02F 1/1368; F21V 8/00; F21K 99/00; H01L 33/06; G02F 1/1333

(52) U.S. Cl. CPC H01L 33/22; H01L 33/06; H01L 33/145; H01L 33/32; H01L 33/382; G02F 1/13306; G02F 1/133345; G02F 1/13439; G02F 1/133514; G02F 1/134309; G02F 1/134336; G02F 1/1368; G02B 6/0073; G02B 6/0055; G02B 6/0068; F21K 9/137; F21K 9/17; F21V 29/70; F21Y 2101/02; F21Y 2103/003

(57) ABSTRACT

Provided is a semiconductor light emitting device including: a light emitting stack including a first semiconductor layer, an active layer and a second semiconductor layer; a first electrode structure penetrating through the second semiconductor layer and the active layer to be connected to the first semiconductor layer, the first electrode structure having at least one contact region; and a second electrode structure connected to the second semiconductor layer, wherein the first semiconductor layer includes a protrusion portion provided on the at least one contact region and a recess portion provided in a circumferential portion of the protrusion portion.

### CROSS-REFERENCE TO RELATED APPLICATION

This application claims priority from Korean Patent Application No. 10-2015-0080005 filed on Jun. 5, 2015, with the Korean Intellectual Property Office, the disclosure of which is incorporated herein by reference in its entirety.

### BACKGROUND

Apparatuses consistent with example embodiments relate to a semiconductor light emitting device.

A semiconductor light emitting diode (LED), a device containing a light emitting material therein to emit light using electrical energy, may convert energy generated due to the recombination of electrons and electron holes into light to be emitted therefrom. Such light emitting diodes (LEDs) have been in widespread use as the light sources of lighting devices and the backlight devices of large liquid crystal displays (LCDs), and accordingly, the development thereof has been accelerated.

With the recent broadening of the scope of application of LEDs, the use of LEDs has been extended to light sources in high current/high output application fields. As LEDs are required in high current/high output application fields as described above, a light emitting device structure having improved light extraction efficiency has been demanded in the technical field.

### SUMMARY

One or more example embodiments may provide a semiconductor light emitting device having improved light extraction efficiency and a method of manufacturing the semiconductor light emitting device.

According to an aspect of an example embodiment there is provided a semiconductor light emitting device including: a light emitting stack including: a first semiconductor layer; an active layer; and a second semiconductor layer; a first electrode structure penetrating through the second semiconductor layer and the active layer to be connected to the first semiconductor layer, the first electrode structure including at least one contact region; and a second electrode structure connected to the second semiconductor layer, wherein the first semiconductor layer includes: a protrusion portion provided on the at least one contact region; and a recess portion provided in a circumferential portion of the protrusion portion.

The protrusion portion may have a cylindrical shape or a polyprismatic shape.

A thickness of the first semiconductor layer in the protrusion portion may be substantially equal to a thickness of the light emitting stack in the recess portion.

An area of the protrusion portion may be smaller than that of the recess portion.

The semiconductor light emitting device may further include a fine unevenness structure provided on the protrusion portion and the recess portion.

A size of the fine unevenness structure may be smaller than that of the protrusion portion.

The fine unevenness structure may have a hemispherical shape, a conical shape or a polypyramidal shape.

The semiconductor light emitting device may further include: a support substrate connected to the first electrode structure; and a bonding electrode connected to the second electrode structure.

The support substrate may be a conductive substrate.

The first electrode structure may include: a first contact electrode disposed in the contact region; and a first pad electrode connected to the first contact electrode, wherein the second electrode structure includes: a second contact electrode being in contact with the second semiconductor layer; and a second pad electrode connected to the second contact electrode, and wherein the first pad electrode and the second pad electrode are disposed on the same side of the light emitting stack.

The first pad electrode and the second pad electrode may be provided on a first surface of the light emitting stack and the protrusion portion may be provided on a second surface opposite to the first surface of the light emitting stack.

A total surface area of the protrusion portion may be smaller than a total surface area of the recess portion in a plan view of the first semiconductor layer.

According to an aspect of another example embodiment there is provided a semiconductor light emitting device including: a light emitting stack including: a first semiconductor layer; an active layer; and a second semiconductor layer; a first electrode structure penetrating through the second semiconductor layer and the active layer to be connected to the first semiconductor layer, the first electrode structure including at least one contact region; and a second electrode structure connected to the second semiconductor layer, wherein the first semiconductor layer includes: a first region provided on the at least one contact region; and a second region provided in a circumferential portion of the first region, and wherein a thickness of the first semiconductor layer in the first region is greater than that of the first semiconductor layer in the second region.

An area of the first region may be smaller than that of the second region.

The light emitting stack may include a group III nitride semiconductor.

The first semiconductor layer may include an n-type nitride semiconductor layer and the second semiconductor layer includes a p-type nitride semiconductor layer.

A total surface area of the first region may be smaller than a total surface area of the second region in a plan view of the first semiconductor layer.

According to an aspect of an example embodiment there is provided A semiconductor light emitting device including: a light emitting stack including: a first semiconductor layer; an active layer; and a second semiconductor layer; a first electrode structure penetrating through the second semiconductor layer and the active layer to be connected to the first semiconductor layer; and a second electrode structure connected to the second semiconductor layer, wherein the first semiconductor layer includes: a first region; and a second region protruding from the first region, and wherein the second region is provided at a region of the first semiconductor layer covering the first electrode structure and the first region is provided at a region of the first semiconductor layer covering the second electrode structure.

A total surface area of the second region may be smaller than a total surface area of the first region in a plan view of the first semiconductor layer.

A thickness of the first semiconductor layer at the second region may be substantially equal to a thickness of the light emitting stack including the first and the second semiconductor layers and the active layer at the first region.

### BRIEF DESCRIPTION OF DRAWINGS

The above and/or other aspects, features and advantages of the disclosure will be more clearly understood from the following detailed description taken in conjunction with the accompanying drawings, in which:

FIG. 1 is a plan view of a semiconductor light emitting device according to an example embodiment;

FIG. 2 is a cross-sectional view of the semiconductor light emitting device according to an example embodiment;

FIGS. 3A through 3I are cross-sectional views illustrating a method of manufacturing the semiconductor light emitting device according to an example embodiment;

FIG. 4 is a plan view of a semiconductor light emitting device according to another example embodiment;

FIG. 5 is a cross-sectional view of the semiconductor light emitting device according to another example embodiment;

FIGS. 6A through 6I are cross-sectional views illustrating a method of manufacturing the semiconductor light emitting device according to another example embodiment;

FIG. 7 is a perspective view of a backlight unit including a semiconductor light emitting device according to an example embodiment;

FIG. 8 is a cross-sectional view of a direct type backlight unit including a semiconductor light emitting device according to an example embodiment;

FIG. 9 is a cross-sectional view illustrating a disposition of light sources in the direct type backlight unit including a semiconductor light emitting device according to an example embodiment;

FIG. 10 is an exploded perspective view of a display device including a semiconductor light emitting device according to an example embodiment;

FIG. 11 is a perspective view of a planar type lighting device including a semiconductor light emitting device according to an example embodiment;

FIG. 12 is an exploded perspective view of a bulb type lamp including a semiconductor light emitting device according to an example embodiment;

FIG. 13 is an exploded perspective view of a bulb type lamp including a communications module and a semiconductor light emitting device according to an example embodiment;

FIG. 14 is an exploded perspective view of a bar type lamp including a semiconductor light emitting device according to an example embodiment; and

FIG. 15 is a schematic view of an indoor lighting control network system including a semiconductor light emitting device according to an example embodiment.

### DETAILED DESCRIPTION

Example embodiments of the present inventive concept will now be described in detail with reference to the accompanying drawings.

The inventive concept may, however, be exemplified in many different forms and should not be construed as being limited to the specific example embodiments set forth herein. Rather, the example embodiments are provided so that this disclosure will be thorough and complete, and will fully convey the scope of the inventive concept to those skilled in the art.

In the drawings, the shapes and dimensions of elements may be exaggerated for clarity, and the same reference numerals will be used throughout to designate the same or like elements.

Semiconductor light emitting devices to be described hereinafter may be variously configured and here, only necessary configurations are exemplified but the inventive concept is not limited thereto.

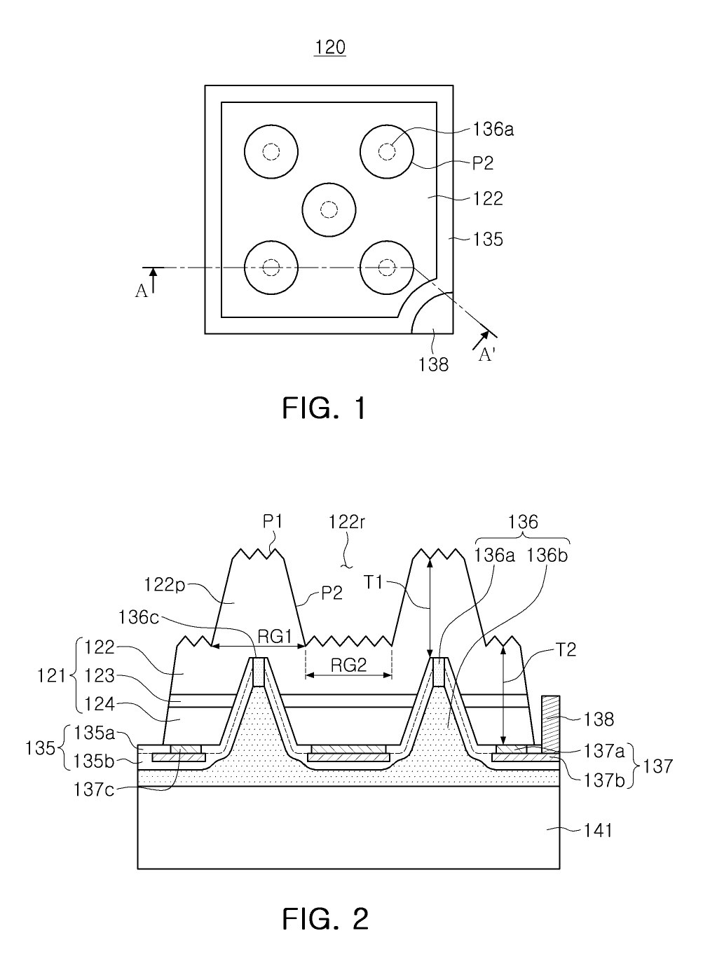

FIG. 1 is a plan view of a semiconductor light emitting device 120 according to an example embodiment. FIG. 2 is a cross-sectional view taken along line A-A′ of FIG. 1.

Referring to FIG. 1 and FIG. 2, the semiconductor light emitting device 120 according to the example embodiment may include a light emitting stack 121 including a first conductivity type semiconductor layer 122, an active layer 123 and a second conductivity type semiconductor layer 124 sequentially stacked therein, and an mesa-etched unevenness structure P2 provided on a surface of the first conductivity type semiconductor layer 122. In addition, the semiconductor light emitting device 120 according to the example embodiment may further include a first electrode structure 136 connected to the first conductivity type semiconductor layer 122, a support substrate 141 connected to the first electrode structure 136, a second electrode structure 137 connected to the second conductivity type semiconductor layer 124, and a bonding electrode 138 connected to the second electrode structure 138.

The light emitting stack 121 may be formed of a group III nitride semiconductor. The first conductivity type semiconductor layer 122 may be a nitride semiconductor satisfying n-type AlₓIn_{y}Ga_{1-x-y}N (0≦x<1, 0≦y<1, 0≦x+y<1), and an n-type dopant may be Si. For example, the first conductivity type semiconductor layer 122 may be n-type GaN. The active layer 123 may emit light having a particular wavelength due to the recombination of electrons and holes. The active layer 123 may have a multiple quantum well (MQW) structure in which quantum well layers and quantum barrier layers are alternately stacked. For example, the active layer 123 may have a structure of GaN/InGaN. The active layer 123 may also have a single-quantum well (SQW) structure. The second conductivity type semiconductor layer 124 may be a nitride semiconductor satisfying p-type AlₓIn_{y}Ga_{1-x-y}N (0≦x<1, 0≦y<1, 0≦x+y<1) and a p-type dopant may be Mg. For example, the second conductivity type semiconductor layer 124 may be p-type GaN.

The electrons having been moved from the first conductivity type semiconductor layer 122 to the active layer 123 may pass through the active layer 123 to overflow to the second conductivity type semiconductor layer 124 without recombination in the active layer 123. The electrons overflowing to the second conductivity type semiconductor layer 124 in such a manner may perform nonradiative recombination, thereby degrading light emission efficiency of the semiconductor light emitting device 120. In order to reduce the electrons overflowing to the second conductivity type semiconductor layer 124, an electron-blocking layer may be provided between the active layer 123 and the second conductivity type semiconductor layer 124. The electron-blocking layer may have an energy band gap greater than that of a final quantum barrier layer. For example, the electron-blocking layer may be formed of AlᵣGa₁₋ᵣN (0<r≦1).

The first electrode structure 136 may penetrate through the second conductivity type semiconductor layer 124 and the active layer 123 to be connected to the first conductivity type semiconductor layer 122 and may have at least one first contact region 136c provided by at least one hole penetrating through the second conductivity type semiconductor layer 124 and the active layer 123 to partially expose the first conductivity type semiconductor layer 122. The first contact region 136c refers to a region in which the first conductivity type semiconductor layer 122 and a first contact electrode 136a are in contact with each other. The first electrode structure 136 may include the first contact electrode 136a disposed in the first contact region 136c and a first connection electrode 136b connected to the first contact electrode 136a. A plurality of first contact electrodes 136a may be disposed in order to reduce contact resistance with the first conductivity type semiconductor layer 122 and to disperse a current in the light emitting device. The number of the first contact electrodes 136a is not limited to that illustrated in the example embodiment. The second electrode structure 137 may include a second contact electrode 137a disposed in a second contact region 137c of the second conductivity type semiconductor layer 124 and a second connection electrode 137b connected to the second contact electrode 137a. The second contact region 137c may be a region in which the second conductivity type semiconductor layer 124 and the second contact electrode 137a are in contact with each other. The second contact electrode 137a may be a single, continuous conductive layer.

The first contact electrode 136a may contain a material capable of forming ohmic-contact with the first conductivity type semiconductor layer 122. The first contact electrode 136a is not particularly limited, and may contain a material such as Ag, Ni, Al, Rh, Pd, Ir, Ru, Mg, Zn, Pt, Au or the like. The first contact electrode 136a may have a structure of a single layer or two or more layers. For example, the first contact electrode 136a may contain Cr/Au or Cr/Au/Pt. If necessary, a barrier layer may be further formed on the first contact electrode 136a. The second contact electrode 137a may contain a material capable of forming ohmic-contact with the second conductivity type semiconductor layer 124. For example, the second contact electrode 137a may contain Ag or Ag/Ni. If necessary, a barrier layer may be further formed on the second contact electrode 137a. The barrier layer may be formed of at least one selected from the group consisting of Ni, Al, Cu, Cr, Ti and combinations thereof. The first and second connection electrodes 136b and 137b may contain a material such as Ag, Ni, Al, Rh, Pd, Ir, Ru, Mg, Zn, Pt, Au, Cu or the like, and may have a single layer or multilayer structure.

The first electrode structure 136 and the second electrode structure 137 may be electrically separated from each other by a passivation layer 135. The passivation layer 135 may include a first insulating layer 135a and a second insulating layer 135b. The first and second insulating layers 135a and 135b may be formed of SiO₂, SiN or SiON.

The first conductivity type semiconductor layer 122 may be provided with the mesa-etched unevenness structure P2 including a protrusion portion 122p provided on the first contact region 136c and a recess portion 122r provided in a circumferential portion of the protrusion portion 122p. The protrusion portion 122p may have a protrusion structure in a first region RG1 corresponding to the first contact electrode 136a. The protrusion portion 122p may have a cylindrical shape or a polyprismatic shape. The recess portion 122r may be provided in the second contact region 137c. The recess portion 122r may have a recessed structure in a second region RG2 corresponding to the second contact electrode 137a. A thickness T1 of the first conductivity type semiconductor layer 122 in the protrusion portion 122p may be substantially identical to a thickness T2 of the light emitting stack 121 in the recess portion 122r. The thickness T1 of the first conductivity type semiconductor layer 122 in the protrusion portion 122p may be greater than that of the first conductivity type semiconductor layer 122 in the recess portion 122r. An area of the protrusion portion 122p may be smaller than that of the recess portion 122r.

As in the example embodiment, a portion of the first conductivity type semiconductor layer 122 may be removed from the second region RG2, whereby a path of light emitted from the active layer 123 may be shortened. Accordingly, the amount of light absorbed by the first conductivity type semiconductor layer 122 may be reduced to improve light extraction efficiency.

A fine unevenness structure P1 may be further provided on the protrusion portion 122p and the recess portion 122r. A size (or diameter) of the fine unevenness structure P1 may be smaller than a size (or diameter) of the protrusion portion 122p. A height of the fine unevenness structure P1 may be lower than a height of the protrusion portion 122p. The fine unevenness structure P1 may have a hemispherical shape, a conical shape or a polypyramidal shape.

The support substrate 141 connected to the first electrode structure 136 may be a conductive substrate and may be bonded to the first electrode structure 136 through a bonding metal layer. The support substrate 141 may contain one of Au, Ni, Al, Cu, W, Si, SiAl, and GaAs.

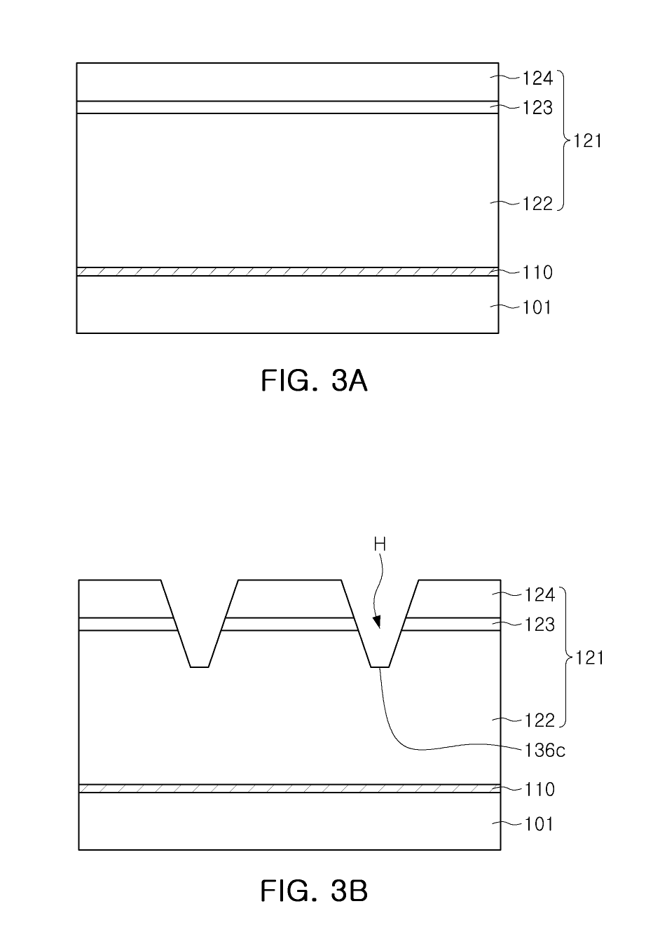

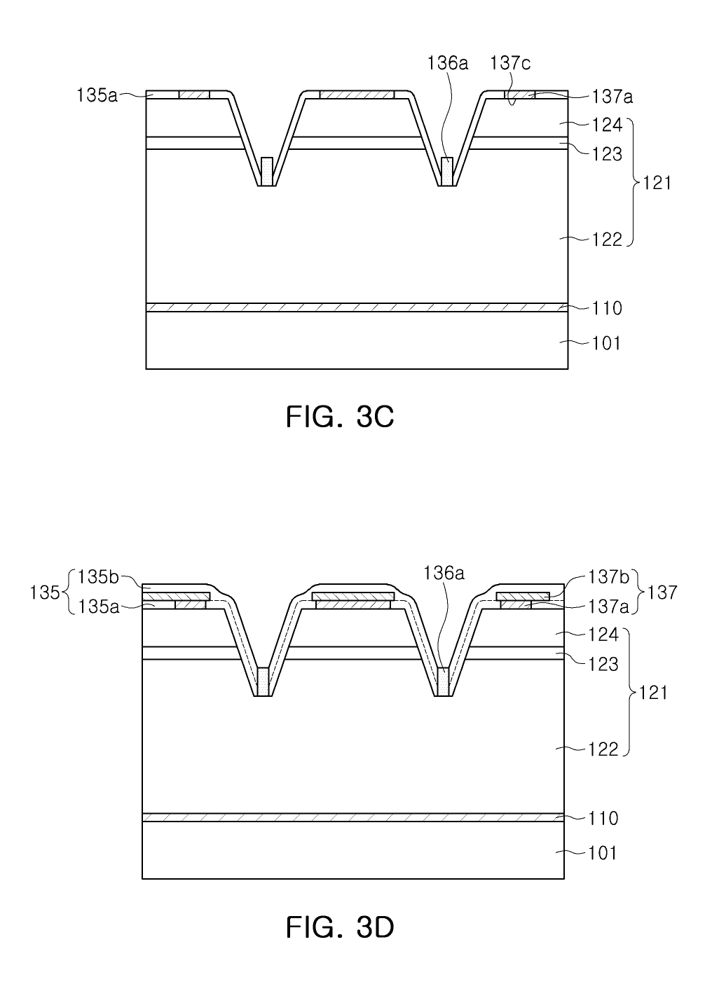

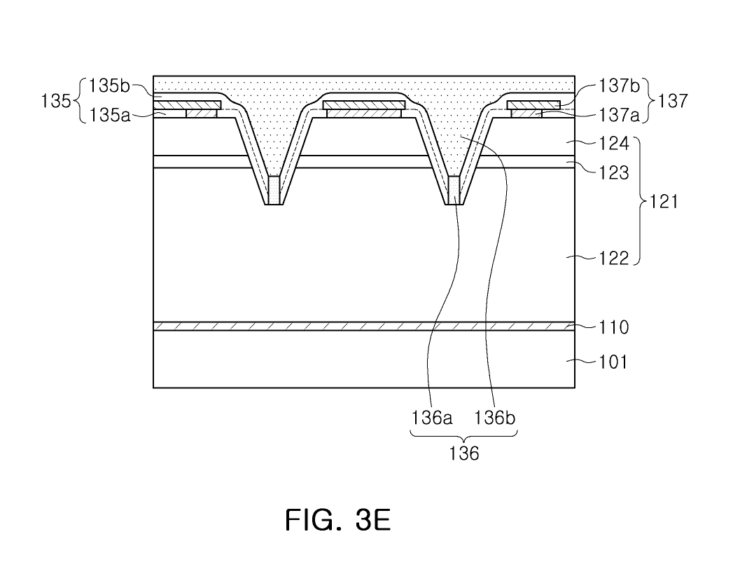

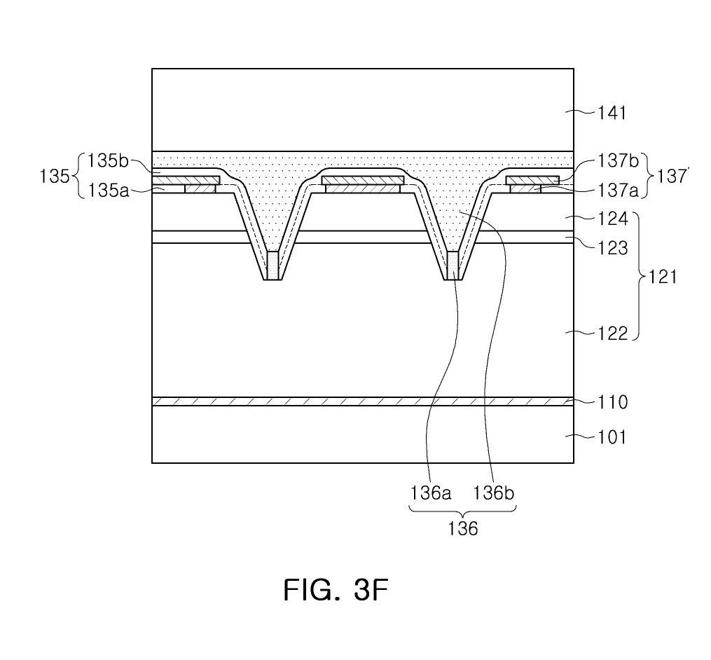

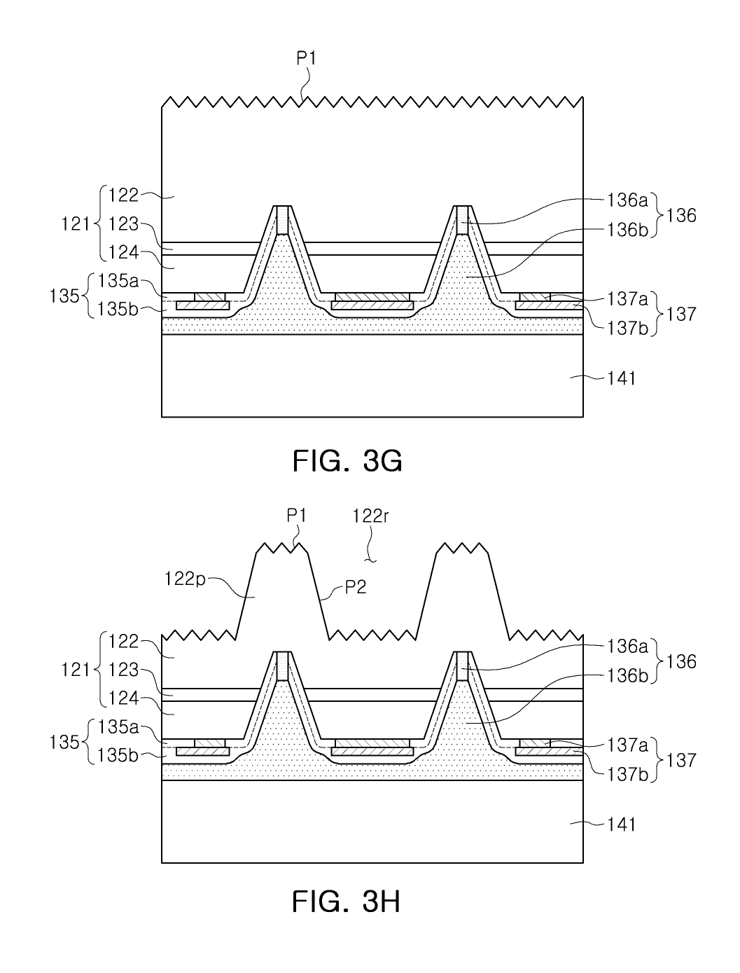

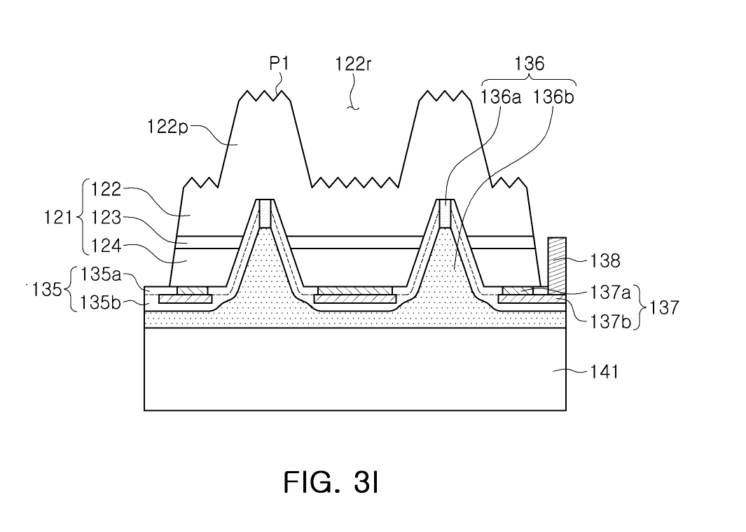

FIGS. 3A through 3I are cross-sectional views illustrating a method of manufacturing the semiconductor light emitting device 120 according to an example embodiment.

Referring to FIG. 3A, a buffer layer 110 may be formed on a growth substrate 101, and the first conductivity type semiconductor layer 122, the active layer 123, and the second conductivity type semiconductor layer 124 may be sequentially grown on the buffer layer 110 to form a light emitting stack 121.

The growth substrate 101 may be sapphire, silicon (Si), silicon carbide (SiC), MgAl₂O₄, MgO, LiAlO₂, LiGaO₂, or GaN. A surface of the growth substrate 101 may include a hemispherical unevenness structure. The shape of the unevenness structure is not limited thereto and may be a polyhedral shape or an irregular unevenness shape.

The buffer layer 110 may be formed on the growth substrate 101 in order to reduce lattice defects of the first conductivity type semiconductor layer 122 by alleviating a difference in lattice constants between the growth substrate 101 and the first conductivity type semiconductor layer 122. For example, when a GaN semiconductor layer serving as the first conductivity type semiconductor layer 122 is grown on the growth substrate 101 formed of sapphire, a material forming the buffer layer 110 may be GaN, AlN, or AlGaN intentionally undoped and formed at a low temperature of 500° C. to 600° C. The buffer layer 110 may be formed of a single layer or a plurality of layers having different compositions.

The buffer layer 110, the first conductivity type semiconductor layer 122, the active layer 123, and the second conductivity type semiconductor layer 124 may be formed using a process such as metal organic chemical vapor deposition (MOCVD), molecular beam epitaxy (MBE) and hydride vapor phase epitaxy (HVPE) or the like. In an example embodiment, the buffer layer 110 may be omitted, and the first conductivity type semiconductor layer 122 may be directly formed on the growth substrate 101.

Next, referring to FIG. 3B, holes H penetrating through the active layer 123 and the second conductivity type semiconductor layer 124 to partially expose the first conductivity type semiconductor layer 122 may be formed. Each of the holes H may be structured for forming the first electrode structure 136 connected to the first conductivity type semiconductor layer 122. Each of exposed portions of the first conductivity type semiconductor layer 122 exposed by the holes H may be provided as a first contact region 136c on which the first contact electrode 136 will be formed later. The process of forming holes H may be performed by a dry etching process using a mask.

Next, referring to FIG. 3C, the first contact electrode 136a connected to the first conductivity type semiconductor layer 122 and the second contact electrode 137a connected to the second conductivity type semiconductor layer 124 may be formed.

First, the first insulating layer 135a may be formed on the entirety of an upper surface of the light emitting stack 121 and may be partially removed such that a portion of the second conductivity type semiconductor layer 124 is exposed by an etching process using a mask. The exposed portion of the second conductivity type semiconductor layer 124 may be provided as the second contact region 137c on which the second contact electrode 137a will be formed. Then, after forming a metal layer on the exposed portion of the second conductivity type semiconductor layer 124, the second contact electrode 137a may be formed by the etching process using a mask.

The first insulating layer 135a may be formed of SiO₂, SiN or SiON. The second contact electrode 137a may contain a material capable of forming ohmic-contact with the second conductivity type semiconductor layer 124.

Next, a portion of the first insulating layer 135a may be removed in order to partially expose the first conductivity type semiconductor layer 122 by an etching process using a mask. The exposed portion of the first conductivity type semiconductor layer 122 may be provided as the first contact region 136c on which the first contact electrode 136a will be formed. Then, after forming a metal layer on the exposed portion of the first conductivity type semiconductor layer 122, the first contact electrode 136a may be formed thereon by an etching process using a mask. The first and second contact electrodes 136a and 137a may be electrically separated from each other by the first insulating layer 135a.

Then, referring to FIG. 3D, the second connection electrode 137b may be formed on the second contact electrode 137a to thereby provide the second electrode structure 137.

After forming a metal layer on the first insulating layer 135a and the second contact electrode 137a, the second connection electrode 137b may be formed by an etching process using a mask. The second connection electrode 137b may be formed wider than the second connection electrode 137b.

Next, after forming an insulating layer on the entirety of an upper surface of the growth substrate 101, the insulating layer may be selectively removed so as to expose only the first contact electrode 136a to thereby form the second insulating layer 135b. The second insulating layer 135b may be formed of SiO₂, SiN or SiON. The second insulating layer 135b may electrically separate the first connection electrode 136b and the second connection electrode 137b to be formed later. The second insulating layer 135b, together with the first insulating layer 135a, may be provided as the passivation layer 135.

Next, referring to FIG. 3E, the first connection electrode 136b connected to the first contact electrode 136a may be formed on the entirety of the upper surface of the growth substrate 101 to thereby provide the first electrode structure 136. The first connection electrode 136b may be electrically connected to the first contact electrode 136a through the holes H. The first electrode structure 136 may be positioned on a surface opposite to the growth substrate 101.

Next, referring to FIG. 3F, the support substrate 141 may be formed on the first connection electrode 136b. The support substrate 141 may be a conductive substrate and in this case, may be provided as a structure connecting the first electrode structure 136 to an external circuit. The support substrate 141 may be bonded to the light emitting stack 121 using the bonding metal layer. In an example embodiment, the support substrate 141 having conductive properties may be formed on a surface of the light emitting stack 121 using a plating process.

Then, referring to FIG. 3G, the growth substrate 101 may be removed. The removal process of the growth substrate 101 may be performed by a substrate separation process using laser beam, a chemical etching process or a mechanical polishing process. In the removing process, the growth substrate 101 may be removed, together with the buffer layer 110. If necessary, a first unevenness structure P1 may be formed on a surface of the first conductivity type semiconductor layer 122 from which the growth substrate 101 has been removed. The first unevenness structure P1 may be formed by performing a dry texturing process. Because the first unevenness structure P1 may reduce total internal reflection on the surface of the first conductivity type semiconductor layer 122, light extraction efficiency may be improved. The dry texturing process may be performed by a reactive ion etch (RIE) process after forming a mask, but is not limited thereto. The dry texturing process may be performed by other dry etching processes commonly known in the technical field. For example, the mask may be a patterned photoresist layer. Unlike this, the first unevenness structure P1 may be formed by a wet texturing process. The wet texturing process may be performed using an etching solution such as a KOH solution. The first unevenness structure P1 may be provided as a fine unevenness structure.

Next, referring to FIG. 3H, a second unevenness structure P2 may be formed in the surface of the first conductivity type semiconductor layer 122.

First, a mask covering a predetermined region (refer to the first region RG1 in FIG. 2) in the upper surface of the first conductivity type semiconductor layer 122 corresponding to a position of the first contact electrode 136a may be formed. For example, the mask may be a patterned photoresist layer. Anisotropic dry etching may be performed on a portion of the first conductivity type semiconductor layer 122 using the mask to thereby form the second unevenness structure P2 including a protrusion portion 122p (refer to the first region RG1 in FIG. 2) formed on the first contact electrode 136a and a recess portion 122r (refer to the second region RG2 in FIG. 2) formed in the circumferential portion of the protrusion portion 122p. A size (or diameter) of the protrusion portion 122p may be greater than a size (or diameter) of the first unevenness structure P1. In the process, also on a surface of the recess portion 122r, the first unevenness structure P1 may be transferred as it is. The second unevenness structure P2 may shorten a path along which light having been emitted from the active layer 123 is discharged outwardly through the first conductivity type semiconductor layer 122, whereby the amount of light absorbed by the first conductivity type semiconductor layer 122 may be reduced. Therefore, the second unevenness structure P2, together with the first unevenness structure P1, may improve light extraction efficiency. The second unevenness structure P2 may be provided as a mesa-etched unevenness structure.

Then, referring to FIG. 3I, the light emitting stack 121 may be separated into individual device units. In this case, the second connection electrode 137b may be partially exposed. Then, the bonding electrode 138 may be formed on the exposed second connection electrode 137b to prepare a desirable semiconductor light emitting device 120. An additional passivation layer may be formed on an exposed side surface of the light emitting stack 121.

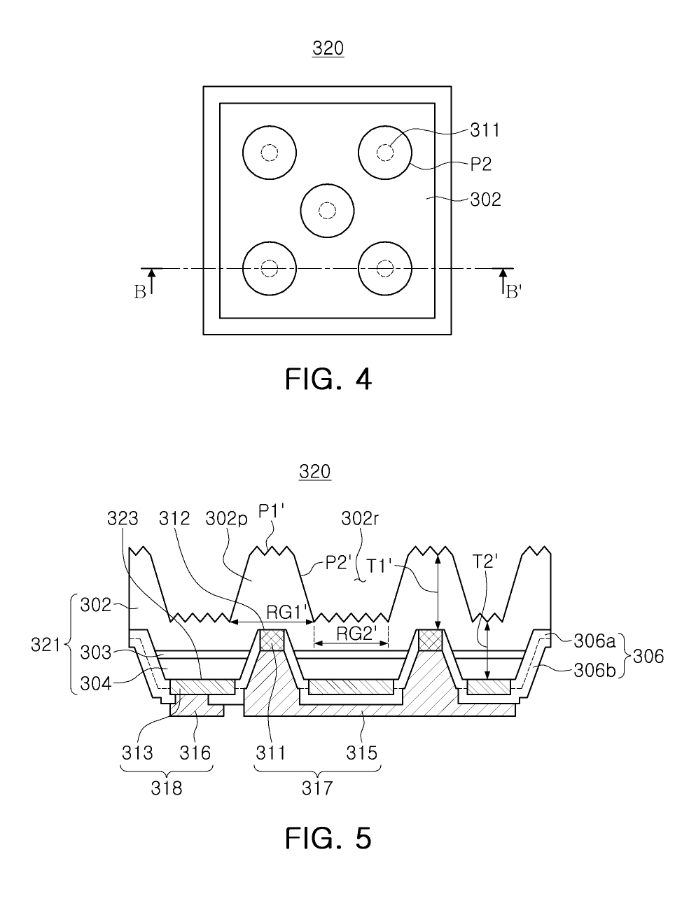

FIG. 4 is a plan view of a semiconductor light emitting device 320 according to an example embodiment. FIG. 5 is a cross-sectional view, taken along line B-B′ of FIG. 4.

Referring to FIG. 4 and FIG. 5, the semiconductor light emitting device 320 according to the example embodiment may include a light emitting stack 321 having a first conductivity type semiconductor layer 302, an active layer 303 and a second conductivity type semiconductor layer 304 sequentially stacked therein, and an mesa-etched unevenness structure P2′ provided on a surface of the first conductivity type semiconductor layer 302. In addition, the semiconductor light emitting device 320 according to the example embodiment may further include a first electrode structure 317 connected to the first conductivity type semiconductor layer 302 and a second electrode structure 318 connected to the second conductivity type semiconductor layer 304.

The light emitting stack 321 may be formed of a group III nitride semiconductor. The first conductivity type semiconductor layer 302 may be a nitride semiconductor satisfying n-type AlₓIn_{y}Ga_{1-x-y}N (0≦x<1, 0≦y<1, 0≦x+y<1), and an n-type dopant may be Si. For example, the first conductivity type semiconductor layer 302 may be n-type GaN. The active layer 303 may emit light having a predetermined wavelength due to the recombination of electrons and holes. The active layer 303 may have a multiple quantum well (MQW) structure in which quantum well layers and quantum barrier layers are alternately stacked. For example, the active layer 303 may have a structure of GaN/InGaN. The active layer 303 may also have a single-quantum well (SQW) structure. The second conductivity type semiconductor layer 304 may be a nitride semiconductor layer satisfying p-type AlₓIn_{y}Ga_{1-x-y}N (0≦x<1, 0≦y<1, 0≦x+y<1) and a p-type dopant may be Mg. For example, the second conductivity type semiconductor layer 304 may be p-type GaN.

In order to reduce electrons overflowing to the second conductivity type semiconductor layer 304, an electron-blocking layer may be provided between the active layer 303 and the second conductivity type semiconductor layer 304. The electron-blocking layer may have an energy band gap greater than that of a final quantum barrier layer. For example, the electron-blocking layer may be formed of AlᵣGa₁₋ᵣN (0<r≦1).

The first electrode structure 317 may penetrate through the second conductivity type semiconductor layer 304 and the active layer 303 to be connected to the first conductivity type semiconductor layer 302 and may have at least one first contact region 312 provided by at least one hole penetrating through the second conductivity type semiconductor layer 304 and the active layer 303 to partially expose the first conductivity type semiconductor layer 302. The first contact region 312 refers to a region in which the first conductivity type semiconductor layer 302 and a first contact electrode 311 are in contact with each other. The first electrode structure 317 may include the first contact electrode 311 disposed in the first contact region 312 and a first pad electrode 315 connected to the first contact electrode 311. A plurality of first contact electrodes 311 may be disposed in order to reduce contact resistance with the first conductivity type semiconductor layer 302 and to disperse a current in the light emitting device. The number of the first contact electrodes 311 is not limited to that illustrated in the example embodiment. The second electrode structure 318 may include a second contact electrode 313 disposed in a second contact region 323 of the second conductivity type semiconductor layer 304 and a second pad electrode 316 connected to the second contact electrode 313. The second contact region 323 may be a region in which the second conductivity type semiconductor layer 304 and the second contact electrode 313 are in contact with each other. The second contact electrode 313 may be a single, continuous conductive layer.

The first contact electrode 311 may contain a material capable of forming ohmic-contact with the first conductivity type semiconductor layer 302. The first contact electrode 311 is not limited, and may contain a material such as Ag, Ni, Al, Rh, Pd, Jr, Ru, Mg, Zn, Pt, Au or the like. The first contact electrode 311 may have a structure of a single layer or two or more layers. For example, the first contact electrode 311 may contain Cr/Au or Cr/Au/Pt. If necessary, a barrier layer may be further formed on the first contact electrode 311. The second contact electrode 313 may contain a material capable of forming ohmic-contact with the second conductivity type semiconductor layer 304. For example, the second contact electrode 313 may contain Ag or Ag/Ni. If necessary, a barrier layer may be further formed on the second contact electrode 313. The barrier layer may be formed of at least one selected from the group consisting of Ni, Al, Cu, Cr, Ti and combinations thereof. The first and second pad electrodes 315 and 316 may contain a material such as Ag, Ni, Al, Rh, Pd, Ir, Ru, Mg, Zn, Pt, Au, Cu or the like, and may have a single layer or multilayer structure.

The first electrode structure 317 and the second electrode structure 318 may be electrically separated from each other by a passivation layer 306. The passivation layer 306 may include a first insulating layer 306a and a second insulating layer 306b. The first and second insulating layers 306a and 306b may be formed of SiO₂, SiN or SiON.

The first conductivity type semiconductor layer 302 may be provided with the mesa-etched unevenness structure P2′ including a protrusion portion 302p provided on the first contact region 312 and a recess portion 302r provided in a circumferential portion of the protrusion portion 302p. The protrusion portion 302p may have a protrusion structure in a first region RG1′ corresponding to the first contact electrode 311. The protrusion portion 302p may have a cylindrical shape or a polyprismatic shape. The recess portion 302r may be provided in the second contact region 323. The recess portion 302r may have a recessed structure in a second region RG2′ corresponding to the second contact electrode 313. A thickness T1′ of the first conductivity type semiconductor layer 302 in the protrusion portion 302p may be substantially identical to a thickness T2′ of the light emitting stack 321 in the recess portion 302r. The thickness T1′ of the first conductivity type semiconductor layer 302 in the protrusion portion 302p may be greater than that of the first conductivity type semiconductor layer 302 in the recess portion 302r. An area of the protrusion portion 302p may be smaller than that of the recess portion 302r.

As in the example embodiment, a portion of the first conductivity type semiconductor layer 302 may be removed from the second region R2′, whereby a path of light emitted from the active layer 303 may be shortened. Accordingly, the amount of light absorbed by the first conductivity type semiconductor layer 302 may be reduced to improve light extraction efficiency.

A fine unevenness structure P1′ may be further provided on the protrusion portion 302p and the recess portion 302r. A size (or diameter) of the fine unevenness structure P1′ may be smaller than a size (or diameter) of the protrusion portion 302p. A height of the fine unevenness structure P1′ may be lower than a height of the protrusion portion 302p. The fine unevenness structure P1′ may have a hemispherical shape, a conical shape or a polypyramidal shape.

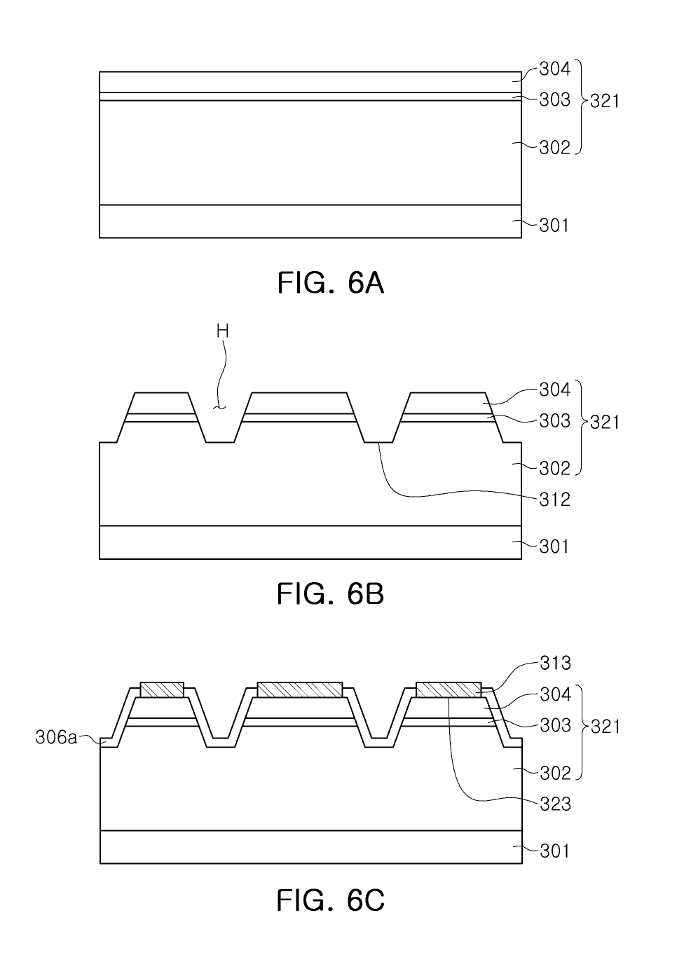

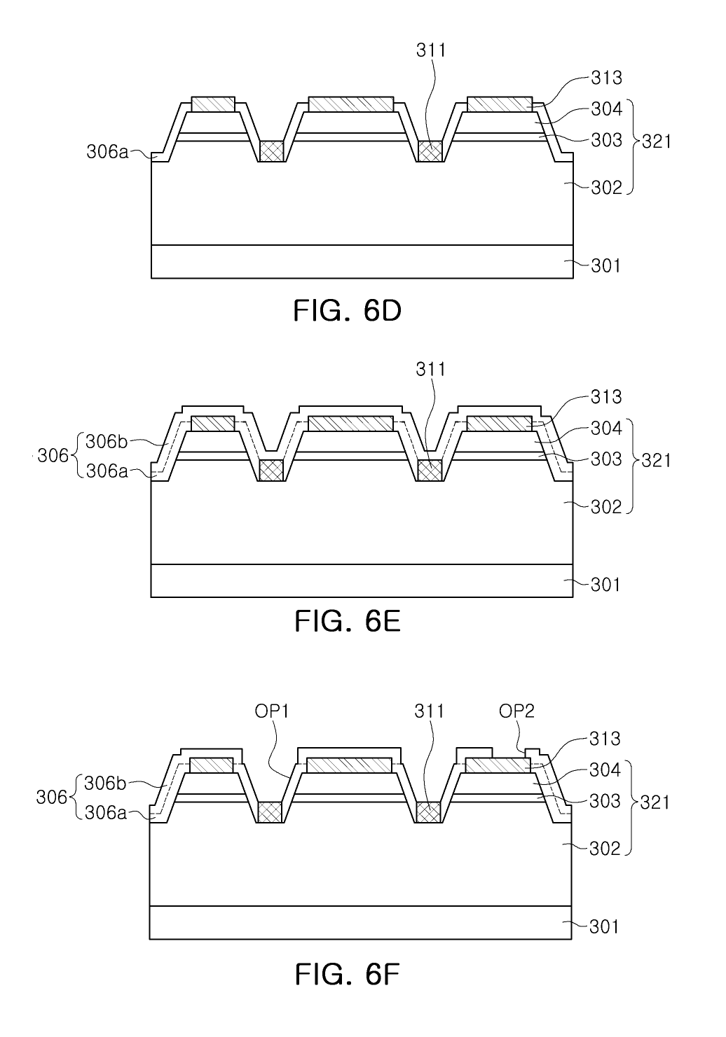

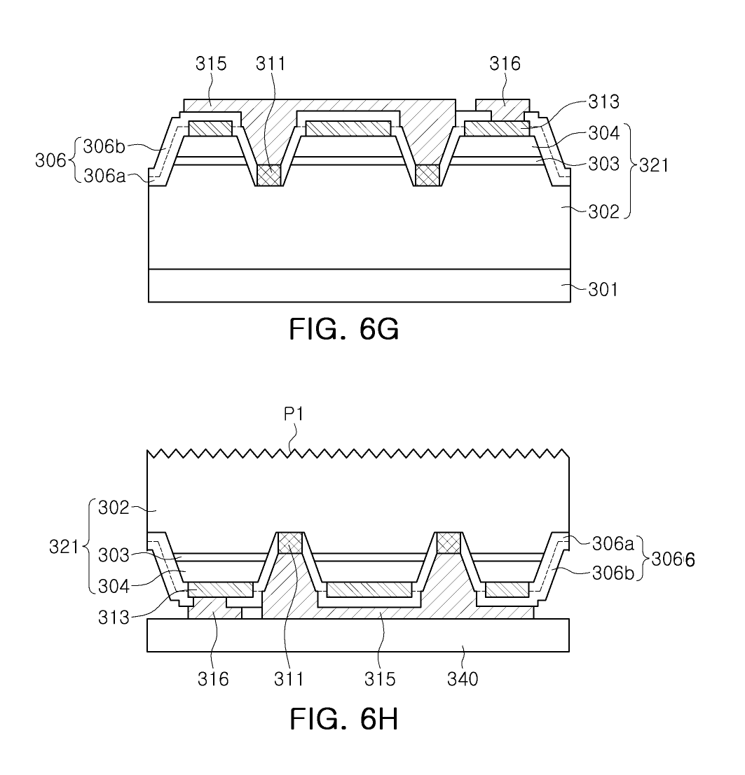

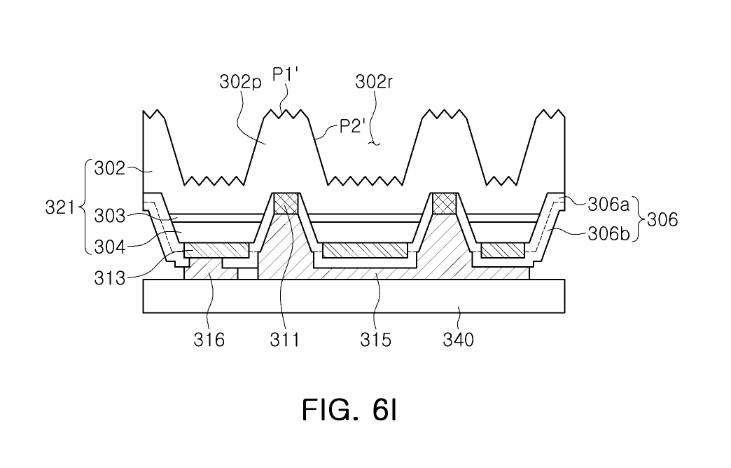

FIGS. 6A through 6I are cross-sectional views illustrating a method of manufacturing the semiconductor light emitting device 320 according to an example embodiment.

Referring to FIG. 6A, the first conductivity type semiconductor layer 302, the active layer 303, and the second conductivity type semiconductor layer 304 may be sequentially grown on a growth substrate 301 to thereby form a light emitting stack 321.

The growth substrate 301 may be sapphire, silicon (Si), silicon carbide (SiC), MgAl₂O₄, MgO, LiAlO₂, LiGaO₂, or GaN. A surface of the growth substrate 301 may include a hemispherical unevenness structure. The shape of the unevenness structure is not limited thereto and may be a polyhedral shape or an irregular unevenness shape.

The light emitting stack 321 may be grown on the growth substrate 301 using a process such as metal organic chemical vapor deposition (MOCVD), molecular beam epitaxy (MBE) and hydride vapor phase epitaxy (HVPE) or the like.

Next, referring to FIG. 6B, holes H penetrating through the active layer 303 and the second conductivity type semiconductor layer 304 to partially expose the first conductivity type semiconductor layer 302 may be formed. Each of the holes H may be structured for forming an electrode connected to the first conductivity type semiconductor layer 302. Each of exposed portions of the first conductivity type semiconductor layer 302 exposed by the holes H may be provided as a first contact region 312 on which the first contact electrode will be formed. The process of forming holes H may be performed by a dry etching process using a mask.

If necessary, referring to FIG. 6B, the first conductivity type semiconductor layer 302 may be additionally exposed by removing an outer circumferential region of the light emitting stack 321, together with forming the holes H. Such an outer circumferential region may be used as a scribing line in a subsequent process of separating the light emitting stack 321 into chip units.

Next, referring to FIG. 6C, the second contact electrode 313 may be formed on an upper surface of the second conductivity type semiconductor layer 304.

First, the first insulating layer 306a may be formed on the entirety of an upper surface of the light emitting stack 321 and may have an open region for the formation of the second contact electrode 313, by an etching process using a mask. A portion of the second conductivity type semiconductor layer 304 exposed by the open region may be provided as the second contact region 323 on which the second contact electrode will be formed. Then, after a metal layer may be deposited on the second conductivity type semiconductor layer 304 exposed by the open region, the second contact electrode 313 may be formed by an etching process using a mask.

The first insulating layer 306a may be formed of SiO₂, SiN or SiON. The second contact electrode 313 may contain a material capable of forming ohmic-contact with the second conductivity type semiconductor layer 304. If necessary, a barrier layer may be further formed on the second contact electrode 313.

Referring to FIG. 6C, the second contact electrode 313 may be widely formed on regions except for a portion adjacent to the edge of the upper surface of the second conductivity type semiconductor layer 304.

Next, referring to FIG. 6D, the first contact electrode 311 may be formed on the upper surface of the first conductivity type semiconductor layer 302.

First, in the first insulating layer 306a, a region for the formation of the first contact electrode 311 may be opened by an etching process using a mask. Then, after a metal layer is deposited on the first conductivity type semiconductor layer 302 exposed by the open region, the first contact electrode 311 may be formed by an etching process using a mask.

The first contact electrode 311 and the second contact electrode 313 may be electrically separated from each other by the first insulating layer 306a.

The first contact electrode 311 may contain a material capable of forming ohmic-contact with the first conductivity type semiconductor layer 302. The first contact electrode 311 may have a structure of a single layer or two or more layers. If necessary, a barrier layer may be further formed on the first contact electrode 311.

Next, referring to FIG. 6E, the second insulating layer 306b may be formed on the upper surface of the light emitting stack 321.

The second insulating layer 306b, together with the first insulating layer 306a, may be provided as the passivation layer 306. The second insulating layer 306b is not limited, and may be formed of a material similar to that of the first insulating layer 306a. For example, the second insulating layer 306b may be formed of SiO₂, SiN or SiON.

Next, referring to FIG. 6F, first and second openings OP1 and OP2 through which portions of the first and second contact electrodes 311 and 313 are exposed may be formed in the second insulating layer 306b.

The second insulating layer 306b may be selectively etched using a mask defining the first and second openings OP1 and OP2 to thereby form the first and second openings OP1 and OP2.

Next, referring to FIG. 6G, the first and second pad electrodes 315 and 316 filling the first and second openings OP1 and OP2 may be formed.

The first pad electrode 315 may be connected to the first contact electrode 311 through the first opening OP1, and the second pad electrode 316 may be connected to the second contact electrode 313 through the second opening OP2. The first pad electrode 315 may be formed to be positioned on a plurality of first openings OP1. The second pad electrode 316 may be formed to be positioned on the second opening OP2. The first pad electrode 315 and the second pad electrode 316 may be separated from each other by a predetermined distance.

Next, referring to FIG. 6H, the growth substrate 301 may be removed, and the first unevenness structure P1′ may be formed on the surface of the first conductivity type semiconductor layer 302.

First, a process of temporarily bonding a support substrate 340 to the first and second pad electrodes 315 and 316 may be performed. A bonding material such as an ultraviolet curing material may be used. Then, the growth substrate 301 may be removed using a process such as a laser-lift off process, but the removal process is not limited thereto. The growth substrate 301 may be removed by other chemical or mechanical processes.

The first unevenness structure P1′ may be formed on the surface of the first conductivity type semiconductor layer 302 by performing a dry texturing process. Because the first unevenness structure P1′ may reduce total internal reflection on the surface of the first conductivity type semiconductor layer 302, light extraction efficiency may be improved. The dry texturing process may be performed by a reactive ion etch (RIE) process after forming a mask, but is not limited thereto. The dry texturing process may be performed by other dry etching processes commonly known in the technical field. For example, the mask may be a patterned photoresist layer. Unlike this, the first unevenness structure P1′ may be formed by a wet texturing process. The wet texturing process may be performed using an etching solution such as a KOH solution. The first unevenness structure P1′ may be provided as a fine unevenness structure.

Next, referring to FIG. 6I, the second unevenness structure P2′ may be formed on the surface of the first conductivity type semiconductor layer 302.

First, a mask covering a predetermined region corresponding to a position of the first contact electrode 311 in the upper surface of the first conductivity type semiconductor layer 302 may be formed. For example, the mask may be a patterned photoresist layer. Anisotropic dry etching may be performed on a portion of the first conductivity type semiconductor layer 302 using the mask to thereby form the second unevenness structure P2′ including a protrusion portion 302p (refer to the first region RG1′ in FIG. 5) formed on the first contact electrode 311 and a recess portion 302r (refer to the second region RG2′ in FIG. 5) formed in the circumferential portion of the protrusion portion 302p. In this case, also on the surface of the etched first conductivity type semiconductor layer 302, the first unevenness structure P1′ may be transferred as it is. The second unevenness structure P2′ may shorten a path along which light having been emitted from the active layer 303 is discharged outwardly through the first conductivity type semiconductor layer 302, whereby the amount of light absorbed by the first conductivity type semiconductor layer 302 may be reduced. Therefore, the second unevenness structure P2′, together with the first unevenness structure P1′, may improve light extraction efficiency. The second unevenness structure P2′ may be provided as a mesa-etched unevenness structure.

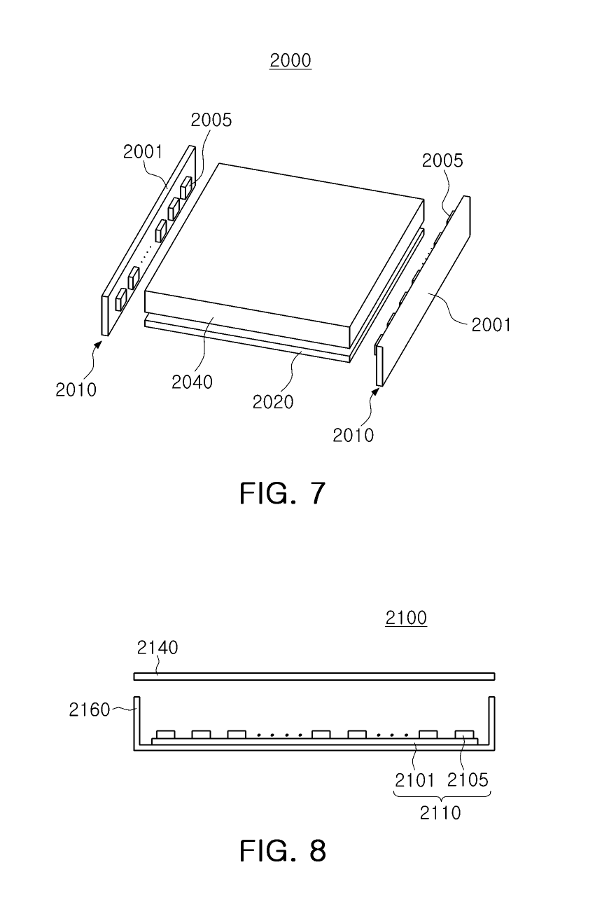

FIG. 7 is a perspective view of a backlight unit including a semiconductor light emitting device 120, 320 according to an example embodiment.

Referring to FIG. 7, a backlight unit 2000 may include a light guide plate 2040 and light source modules 2010 provided on both sides of the light guide plate 2040. Also, the backlight unit 2000 may further include a reflective plate 2020 disposed below the light guide plate 2040. The backlight unit 2000 according to the example embodiment may be an edge type backlight unit.

According to an example embodiment, the light source module 2010 may be provided only on one side of the light guide plate 2040 or may further be provided on the other side thereof. The light source module 2010 may include a printed circuit board (PCB) 2001 and a plurality of light sources 2005 mounted on an upper surface of the PCB 2001. Here, the light sources 2005 may include the semiconductor light emitting devices 120, 320 according to the example embodiments.

FIG. 8 is a cross-sectional view of a direct type backlight unit including a semiconductor light emitting device 120, 320 according to an example embodiment.

Referring to FIG. 8, a backlight unit 2100 may include a light diffuser plate 2140 and a light source module 2110 arranged below the light diffuser plate 2140. Also, the backlight unit 2100 may further include a bottom case 2160 disposed below the light diffuser plate 2140 and accommodating the light source module 2110. The backlight unit 2100 according to the example embodiment may be a direct type backlight unit.

The light source module 2110 may include a printed circuit board (PCB) 2101 and a plurality of light sources 2105 mounted on an upper surface of the PCB 2101. Here, the light sources 2105 may include the semiconductor light emitting devices 120, 320 according to the example embodiments.

FIG. 9 is a cross-sectional view illustrating a disposition of light sources in the direct type backlight unit including a semiconductor light emitting device 120 according to an example embodiment.

A direct type backlight unit 2200 according to the example embodiment may be configured to include a plurality of light sources 2205 arranged on a board 2201. Here, the light sources 2205 may include the semiconductor light emitting devices 120, 320 according to the example embodiments discussed previously.

The arrangement structure of the light sources 2205 is a matrix structure in which the light sources 2205 are arranged in rows and columns, and here, the rows and columns have a zigzag form. This is a structure in which a second matrix having the same form as that of a first matrix is disposed within the first matrix in which the plurality of light sources 2205 are arranged in rows and columns in straight lines, which may be understood as each light source 2205 of the second matrix being positioned within a quadrangle formed by four adjacent light sources 2205 included in the first matrix. In other words, the light sources 2205 of each of the rows are offset from corresponding light sources 2205 adjacent rows and the light sources 2205 of each of columns are offset from corresponding light sources 2205 adjacent columns as shown in the figure.

However, in the direct type backlight unit 2200, in order to enhance uniformity of luminance and light efficiency, the first and second matrices may have different disposition structures and intervals, if necessary. Also, in addition to the method of disposing the plurality of light sources, distances S1 and S2 between adjacent light sources may be optimized to secure uniformity of luminance.

In this manner, because the rows and columns of the light sources 2205 are disposed in a zigzag manner, rather than being disposed in straight lines, the number of the light sources 2205 may be reduced by about 15% to 25% in comparison with a backlight unit having the same light emitting area.

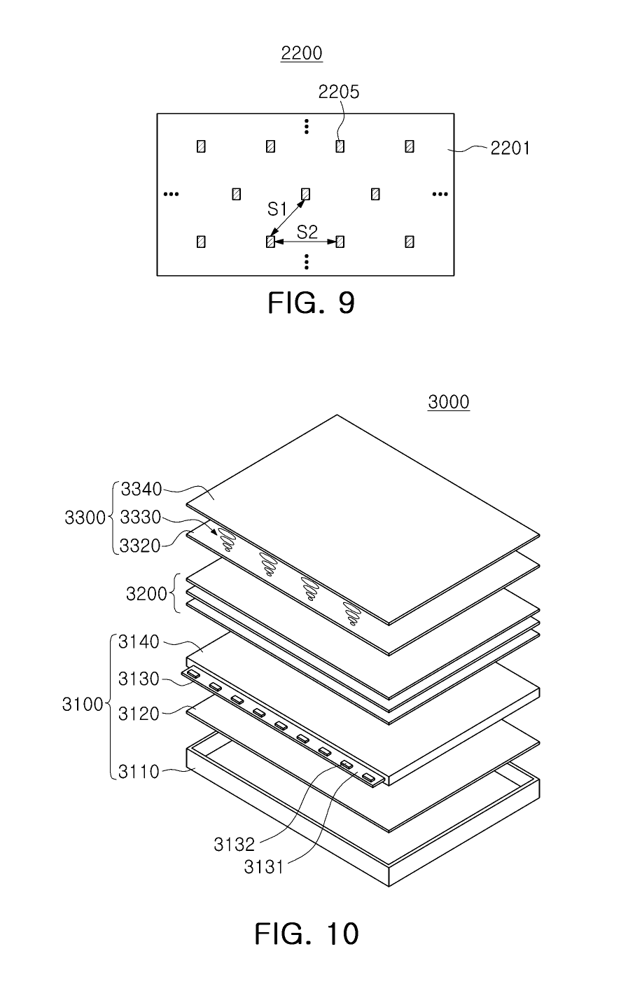

FIG. 10 is an exploded perspective view of a display device including a semiconductor light emitting device 120, 320 according to an example embodiment.

Referring to FIG. 10, a display device 3000 may include a backlight unit 3100, an optical sheet 3200, and an image display panel 3300 such as a liquid crystal panel.

The backlight unit 3100 may include a bottom case 3110, a reflective plate 3120, a light guide plate 3140, and a light source module 3130 provided on at least one side of the light guide plate 3140. The light source module 3130 may include a PCB 3131 and light sources 3132. In particular, the light source 3132 may be a side view type light emitting device having a side surface adjacent to a light emission surface and serving as a mounting surface. Here, the light sources 3132 may include the semiconductor light emitting devices 120 according to the example embodiments.

The optical sheet 3200 may be disposed between the light guide plate 3140 and the image display panel 3300 and may include various types of sheets such as a diffusion sheet, a prism sheet, and a protective sheet.

The image display panel 3300 may display an image using light output from the optical sheet 3200. The image display panel 3300 may include an array substrate 3320, a liquid crystal layer 3330, and a color filter substrate 3340. The array substrate 3320 may include pixel electrodes disposed in a matrix form, thin film transistors (TFTs) applying a driving voltage to the pixel electrodes, and signal lines operating the TFTs. The color filter substrate 3340 may include a transparent substrate, a color filter, and a common electrode. The color filter may include filters allowing light having a particular wavelength, included in white light emitted from the backlight unit 3100, to selectively pass therethrough. Liquid crystals in the liquid crystal layer 3330 are rearranged by an electric field applied between the pixel electrodes and the common electrode, and thereby light transmittance is adjusted. The light with transmittance thereof adjusted may pass through the color filter of the color filter substrate 3340, thus displaying an image. The image display panel 3300 may further include a driving circuit unit processing an image signal, or the like.

The display device 3000 according to the example embodiment uses the light sources 3132 emitting blue light, green light, and red light having a relatively small FWHM. Thus, emitted light, after having passing through the color filter substrate 3340, may implement blue, green, and red light having a high level of color purity.

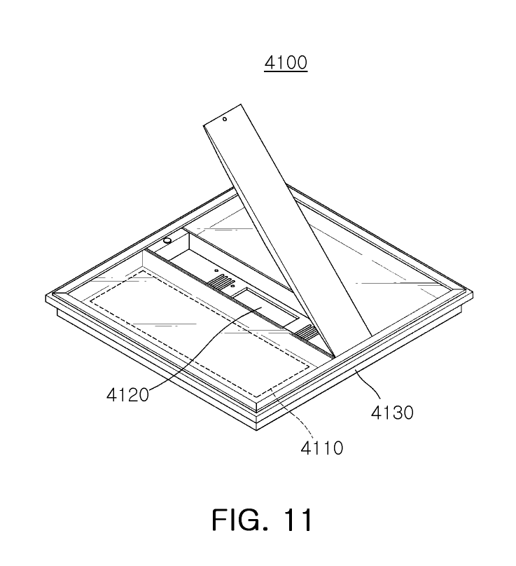

FIG. 11 is a perspective view of a planar type lighting device including a semiconductor light emitting device 120, 320 according to an example embodiment.

Referring to FIG. 11, a planar type lighting device 4100 may include a light source module 4110, a power supply device 4120, and a housing 4130. According to an example embodiment, the light source module 4110 may include a light emitting device array as a light source, and the power supply device 4120 may include a light emitting device driving unit.

The light source module 4110 may include a light emitting device array and may be formed to have an overall planar shape. The light emitting device array may include a light emitting device and a controller storing driving information of the light emitting device. The light emitting device may be the semiconductor light emitting device 120 according to the example embodiment.

The power supply device 4120 may be configured to supply power to the light source module 4110. The housing 4130 may have an accommodation space accommodating the light source module 4110 and the power supply device 4120 therein and have a hexahedral shape with one open side, but the shape of the housing 4130 is not limited thereto. The light source module 4110 may be disposed to emit light to the open side of the housing 4130.

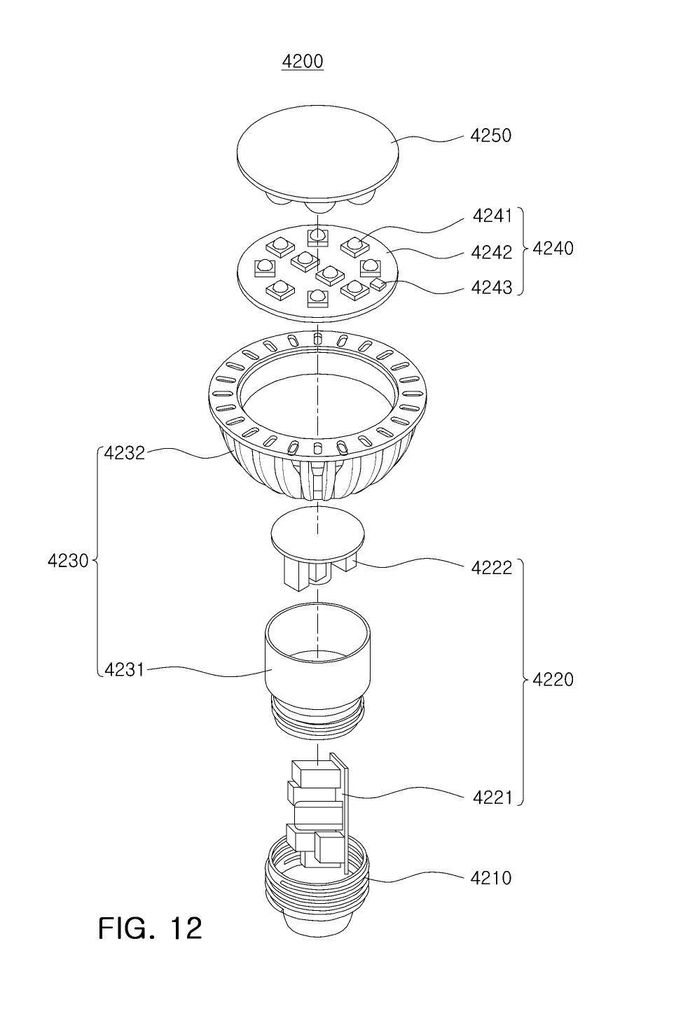

FIG. 12 is an exploded perspective view of a bulb type lamp including a semiconductor light emitting device 120 according to an example embodiment.

Referring to FIG. 12, a lighting device 4200 may include a socket 4210, a power source unit 4220, a heat dissipation unit 4230, a light source module 4240, and an optical unit 4250. The light source module 4240 may include a light emitting device array, and the power source unit 4220 may include a light emitting device driving unit.

The socket 4210 may be configured to be replaced with an existing lighting device. Power supplied to the lighting device 4200 may be applied through the socket 4210. As illustrated, the power source unit 4220 may include a first power source unit 4221 and a second power source unit 4222. The first power source unit 4221 and the second power source unit 4222 may be separately provided and assembled to form the power source unit 4220. The heat dissipation unit 4230 may include an internal heat dissipation unit 4231 and an external heat dissipation unit 4232. The internal heat dissipation unit 4231 may be directly connected to the light source module 4240 and/or the power source unit 4220 to thereby transmit heat to the external heat dissipation unit 4232. The optical unit 4250 may include an internal optical unit (not shown) and an external optical unit (not shown) and may be configured to evenly distribute light emitted by the light source module 4240.

The light source module 4240 may emit light to the optical unit 4250 upon receiving power from the power source unit 4220. The light source module 4240 may include one or more light emitting devices 4241, a circuit board 4242, and a controller 4243. The controller 4243 may store driving information of the light emitting devices 4241. The light emitting device 4241 may be the semiconductor light emitting device 120 according to the example embodiment.

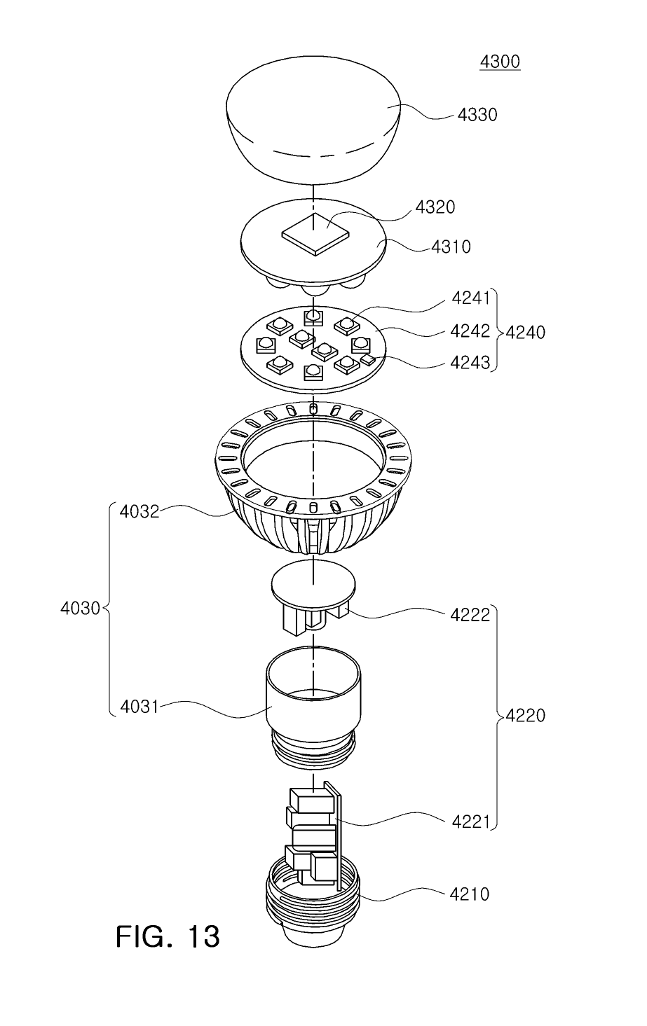

FIG. 13 is an exploded perspective view of a bulb type lamp including a communications module and a semiconductor light emitting device 120 according to an example embodiment.

Referring to FIG. 13, a lighting device 4300 according to the present example embodiment is different from the lighting device 4200 illustrated in FIG. 12, in that a reflective plate 4310 is provided above the light source module 4240, and here, the reflective plate 4310 serves to allow light from the light source to spread evenly toward the lateral sides and back side thereof, and thereby glare may be reduced.

A communications module 4320 may be mounted on an upper portion of the reflective plate 4310, and home network communications may be realized through the communications module 4320. For example, the communications module 4320 may be a wireless communications module using ZigBee, Wi-Fi, or light fidelity (Li-Fi), and may control lighting installed in the interior or on the exterior of a household, such as turning a lighting device on or off, adjusting the brightness of a lighting device, and the like, through a smartphone or a wireless controller. Also, home appliances or an automobile system in the interior or on the exterior of a household, such as a TV, a refrigerator, an air-conditioner, a door lock, or automobiles, and the like, may be controlled through a Li-Fi communications module using visible wavelengths of the lighting device installed in the interior or on the exterior of the household.

The reflective plate 4310 and the communications module 4320 may be covered by a cover unit 4330.

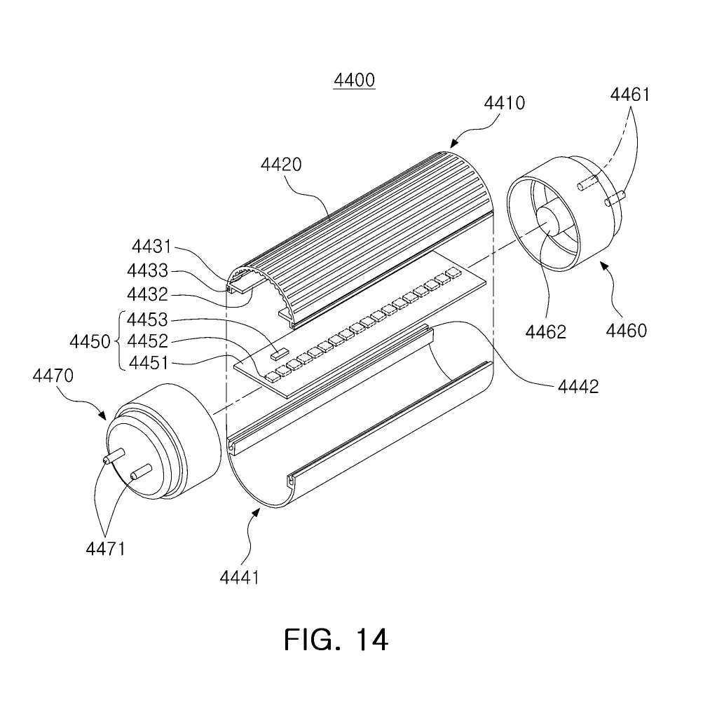

FIG. 14 is an exploded perspective view of a bar type lamp including a semiconductor light emitting device 120 according to an example embodiment.

Referring to FIG. 14, a lighting device 4400 includes a heat dissipation member 4410, a cover 4441, a light source module 4450, a first socket 4460, and a second socket 4470. A plurality of heat dissipation fins 4420 and 4431 may be formed in a concavo-convex pattern on an internal or/and external surface of the heat dissipation member 4410, and the heat dissipation fins 4420 and 4431 may be designed to have various shapes and intervals (spaces) therebetween. A support portion 4432 having a protruded shape may be formed on an inner side of the heat dissipation member 4410. The light source module 4450 may be fixed to the support portion 4432. Stoppage protrusions 4433 may be formed on both ends of the heat dissipation member 4410.

The stoppage recesses 4442 may be formed in the cover 4441, and the stoppage protrusions 4433 of the heat dissipation member 4410 may be coupled to the stoppage recesses 4442. The positions of the stoppage recesses 4442 and the stoppage protrusions 4433 may be interchanged.

The light source module 4450 may include a light emitting device array. The light source module 4450 may include a PCB 4451, a light source 4452 having an optical device, and a controller 4453. As described above, the controller 4453 may store driving information of the light source 4452. Circuit wirings are formed on the PCB 4451 to operate the light source 4452. Also, components for operating the light source 4452 may be provided. The light source 4452 may include the semiconductor light emitting device 120 according to the example embodiment.

The first and second sockets 4460 and 4470, a pair of sockets, are respectively coupled to opposing ends of the cylindrical cover unit including the heat dissipation member 4410 and the cover 4441. For example, the first socket 4460 may include electrode terminals 4461 and a power source device 4462, and dummy terminals 4471 may be disposed on the second socket 4470. Also, an optical sensor and/or a communications module may be installed in either the first socket 4460 or the second socket 4470. For example, the optical sensor and/or the communications module may be installed in the second socket 4470 in which the dummy terminals 4471 are disposed. In another example, the optical sensor and/or the communications module may be installed in the first socket 4460 in which the electrode terminals 4461 are disposed.

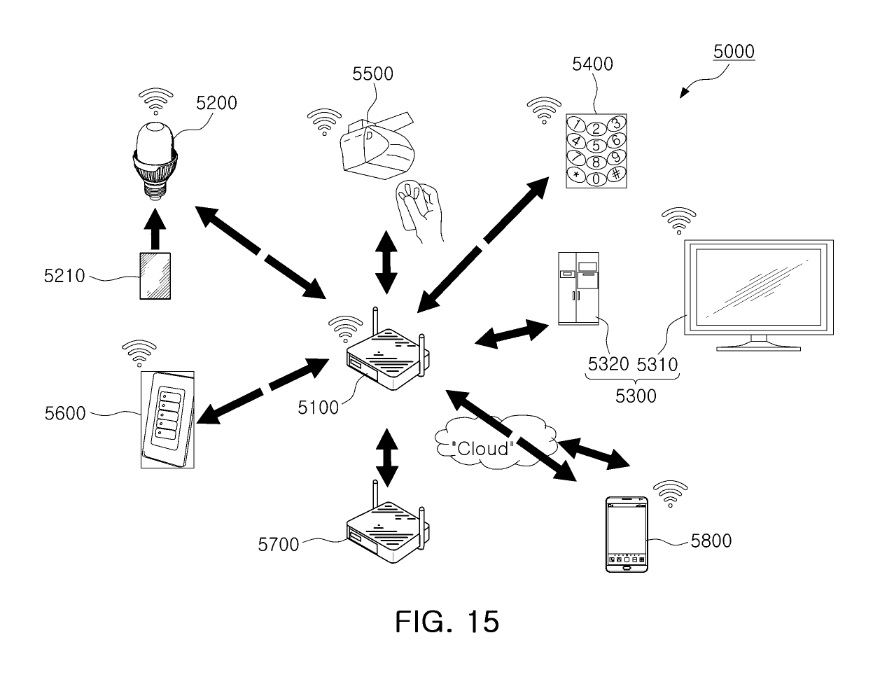

FIG. 15 is a schematic view of an indoor lighting control network system including a semiconductor light emitting device 120 according to an example embodiment.

A network system 5000 may be a complex smart lighting-network system combining a lighting technology using a light emitting device such as an LED, or the like, Internet of things (IoT) technology, a wireless communications technology, and the like. The network system 5000 may be realized using various lighting devices and wired/wireless communications devices, and may be realized by a sensor, a controller, a communications unit, software for network control and maintenance, and the like.

The network system 5000 may be applied even to an open space such as a park or a street, as well as to a closed space such as a house or an office. The network system 5000 may be realized on the basis of the IoT environment in order to collect and process a variety of information and provide the same to users. Here, an LED lamp 5200 included in the network system 5000 may serve not only to receive information regarding a surrounding environment from a gateway 5100 and control lighting of the LED lamp 5200 itself, but also to determine and control operational states of other devices 5300 to 5800 included in the IoT environment on the basis of a function such as visible light communications, or the like, of the LED lamp 5200.

Referring to FIG. 15, the network system 5000 may include the gateway 5100 processing data transmitted and received according to different communications protocols, the LED lamp 5200 connected to be available for communicating with the gateway 5100 and including an LED light emitting device, and a plurality of devices 5300 to 5800 connected to be available for communicating with the gateway 5100 according to various wireless communications schemes. In order to realize the network system 5000 on the basis of the IoT environment, each of the devices 5300 to 5800, as well as the LED lamp 5200, may include at least one communications module. In an example embodiment, the LED lamp 5200 may be connected to be available for communicating with the gateway 5100 according to wireless communication protocols such as Wi-Fi, ZigBee, or Li-Fi, and to this end, the LED lamp 5200 may include at least one communications module 5210 for a lamp. The LED lamp 5200 may include the semiconductor light emitting devices 120 according to the example embodiments.

As mentioned above, the network system 5000 may be applied even to an open space such as a park or a street, as well as to a closed space such as a house or an office. When the network system 5000 is applied to a house, the plurality of devices 5300 to 5800 included in the network system and connected to be available for communicating with the gateway 5100 on the basis of the IoT technology may include a home appliance 5300, a digital door lock 5400, a garage door lock 5500, a light switch 5600 installed on a wall, or the like, a router 5700 for relaying a wireless communications network, and a mobile device 5800 such as a smartphone, a tablet PC, or a laptop computer.

In the network system 5000, the LED lamp 5200 may determine operational states of various devices 5300 to 5800 using the wireless communications network (ZigBee, Wi-Fi, LI-Fi, etc.) installed in a household or automatically control illumination of the LED lamp 5200 itself according to a surrounding environment or situation. Also, the devices 5300 to 5800 included in the network system 5000 may be controlled using Li-Fi communications using visible light emitted from the LED lamp 5200.

First, the LED lamp 5200 may automatically adjust illumination of the LED lamp 5200 on the basis of information of a surrounding environment transmitted from the gateway 5100 through the communications module 5210 for a lamp or information of a surrounding environment collected from a sensor installed in the LED lamp 5200. For example, brightness of illumination of the LED lamp 5200 may be automatically adjusted according to types of programs broadcast on the TV 5310 or brightness of a screen. To this end, the LED lamp 5200 may receive operation information of the TV 5310 from the communications module 5210 for a lamp connected to the gateway 5100. The communications module 5210 for a lamp may be integrally modularized with a sensor and/or a controller included in the LED lamp 5200.

For example, when a program value broadcast in a TV program is a drama, a color temperature of illumination may be decreased to be 12000K or lower, for example, to 5000K, and a color tone may be adjusted according to preset values, and thereby a cozy atmosphere is created. Conversely, when a program value is a comedy program, the network system 5000 may be configured so that a color temperature of illumination is increased to 5000K or higher according to a preset value, and illumination is adjusted to white illumination based on blue light.

Also, when there is no one at home, and a predetermined time has lapsed after digital door lock 5400 is locked, all of the turned-on LED lamps 5200 are turned off to prevent a waste of electricity. Also, when a security mode is set through the mobile device 5800, or the like, and the digital door lock 5400 is locked with no one at home the LED lamp 5200 may be maintained in a turned-on state.

An operation of the LED lamp 5200 may be controlled according to surrounding environments collected through various sensors connected to the network system 5000. For example, when the network system 5000 is realized in a building, a lighting apparatus, a position sensor, and a communications module are combined in the building, and position information of people in the building is collected and the lighting apparatus is turned on or turned off, or the collected information may be provided in real time to effectively manage facilities or effectively utilize an idle space. In the related art, a lighting device such as the LED lamp 5200 is disposed in almost every space of each floor of a building, and thus, various types of information of the building may be collected through a sensor integrally provided with the LED lamp 5200 and used for managing facilities and utilizing an idle space.

Meanwhile, the LED lamp 5200 may be combined with an image sensor, a storage device, and the communications module 5210 for a lamp, to be utilized as a device for maintaining building security, or sensing and coping with an emergency situation. For example, when a sensor of smoke or temperature, or the like, is attached to the LED lamp 5200, a fire may be promptly sensed to minimize damage. Also, brightness of lighting may be adjusted in consideration of outside weather or an amount of sunshine, thereby saving energy and providing an agreeable illumination environment.

As set forth above, according to example embodiments, a semiconductor light emitting device having improved light extraction efficiency may be provided by reducing an absorption amount of light emitted from an active layer through the removal of a portion of a semiconductor layer providing a main light emission surface.

While example embodiments have been particularly shown and described above, it will be apparent to those skilled in the art that various changes may be made without departing from the scope of the inventive concept as defined by the following claims.

What is claimed is:

1. A semiconductor light emitting device comprising:
a light emitting stack comprising:
a first semiconductor layer;
an active layer; and
a second semiconductor layer;
a first electrode structure penetrating through the second semiconductor layer and the active layer to be connected to the first semiconductor layer, the first electrode structure comprising at least one contact region; and
a second electrode structure connected to the second semiconductor layer,
wherein the first semiconductor layer comprises:
a protrusion portion provided on the at least one contact region; and
a recess portion provided in a circumferential portion of the protrusion portion.

2. The semiconductor light emitting device of claim 1, wherein the protrusion portion has a cylindrical shape or a polyprismatic shape.

3. The semiconductor light emitting device of claim 1, wherein a thickness of the first semiconductor layer in the protrusion portion is substantially equal to a thickness of the light emitting stack in the recess portion.

4. The semiconductor light emitting device of claim 1, wherein an area of the protrusion portion is smaller than that of the recess portion.

5. The semiconductor light emitting device of claim 1, further comprising a fine unevenness structure provided on the protrusion portion and the recess portion.

6. The semiconductor light emitting device of claim 5, wherein a size of the fine unevenness structure is smaller than that of the protrusion portion.

7. The semiconductor light emitting device of claim 5, wherein the fine unevenness structure has a hemispherical shape, a conical shape or a polypyramidal shape.

8. The semiconductor light emitting device of claim 1, further comprising:
a support substrate connected to the first electrode structure; and
a bonding electrode connected to the second electrode structure.

9. The semiconductor light emitting device of claim 8, wherein the support substrate is a conductive substrate.

10. The semiconductor light emitting device of claim 1, wherein the first electrode structure comprises:
a first contact electrode disposed in the contact region; and
a first pad electrode connected to the first contact electrode, wherein the second electrode structure comprises:
a second contact electrode being in contact with the second semiconductor layer; and
a second pad electrode connected to the second contact electrode, and
wherein the first pad electrode and the second pad electrode are disposed on the same side of the light emitting stack.

11. The semiconductor light emitting device of claim 10, wherein the first pad electrode and the second pad electrode are provided on a first surface of the light emitting stack and the protrusion portion is provided on a second surface opposite to the first surface of the light emitting stack.

12. The semiconductor light emitting device of claim 1, wherein a total surface area of the protrusion portion is smaller than a total surface area of the recess portion in a plan view of the first semiconductor layer.

13. A semiconductor light emitting device comprising:
a light emitting stack comprising:
a first semiconductor layer;
an active layer; and
a second semiconductor layer;
a first electrode structure penetrating through the second semiconductor layer and the active layer to be connected to the first semiconductor layer, the first electrode structure comprising at least one contact region; and
a second electrode structure connected to the second semiconductor layer,
wherein the first semiconductor layer comprises:
a first region provided on the at least one contact region; and
a second region provided in a circumferential portion of the first region, and
wherein a thickness of the first semiconductor layer in the first region is greater than that of the first semiconductor layer in the second region.

14. The semiconductor light emitting device of claim 13, wherein an area of the first region is smaller than that of the second region.

15. The semiconductor light emitting device of claim 13, wherein the light emitting stack comprises a group III nitride semiconductor.

16. The semiconductor light emitting device of claim 13, wherein the first semiconductor layer comprises an n-type nitride semiconductor layer and the second semiconductor layer comprises a p-type nitride semiconductor layer.

17. The semiconductor light emitting device of claim 13, wherein a total surface area of the first region is smaller than a total surface area of the second region in a plan view of the first semiconductor layer.

18. A semiconductor light emitting device comprising:
a light emitting stack comprising:
a first semiconductor layer;
an active layer; and
a second semiconductor layer;
a first electrode structure penetrating through the second semiconductor layer and the active layer to be connected to the first semiconductor layer; and
a second electrode structure connected to the second semiconductor layer,
wherein the first semiconductor layer comprises:
a first region; and
a second region protruding from the first region, and
wherein the second region is provided at a region of the first semiconductor layer covering the first electrode structure and the first region is provided at a region of the first semiconductor layer covering the second electrode structure.

19. The semiconductor light emitting device of claim 18, wherein a total surface area of the second region is smaller than a total surface area of the first region in a plan view of the first semiconductor layer.

20. The semiconductor light emitting device of claim 18, wherein a thickness of the first semiconductor layer at the second region is substantially equal to a thickness of the light emitting stack including the first and the second semiconductor layers and the active layer at the first region.
